(19) United States
(12) Patent Application Publication
(10) Pub. No.: US 2024/0178276 A1
(43) Pub. Date: May 30, 2024

(54) SEMICONDUCTOR DEVICE

(71) Applicant: ROHM CO., LTD., Kyoto (JP)

(72) Inventors: Satoshi IWAHASHI, Kyoto (JP); Jun KOBAYASHI, Kyoto (JP); Kazuyoshi MAKI, Kyoto (JP)

(73) Assignee: ROHM CO., LTD., Kyoto (JP)

(21) Appl. No.: 18/522,276

(22) Filed: Nov. 29, 2023

(30) Foreign Application Priority Data
Nov. 30, 2022 (JP) 2022-192214

(51) Int. Cl. H01L 29/06; H01L 29/66

(52) U.S. Cl. CPC H01L 29/0688; H01L 29/0657; H01L 29/66545

(57) ABSTRACT

There is provided a semiconductor device including a semiconductor layer having a first conductivity type and including a first surface and a second surface on an opposite side of the first surface, a plurality of element structures formed in the first surface of the semiconductor layer at equal intervals in one direction, and a super junction structure formed in the semiconductor layer.

### CROSS-REFERENCE TO RELATED APPLICATION

This application is based upon and claims the benefit of priority from Japanese Patent Application No. 2022-192214, filed on Nov. 30, 2022, the entire contents of which are incorporated herein by reference.

### TECHNICAL FIELD

The present disclosure relates to a semiconductor device.

### BACKGROUND

In the related art, there is known a MOSFET. In this MOSFET, a super junction structure is provided between a semiconductor substrate containing an n+-type impurity and a base layer containing a p-type impurity. In the super junction structure, a first semiconductor layer containing an n-type impurity and a second semiconductor layer containing a p-type impurity are alternately and repeatedly arranged in a direction intersecting a direction in which the semiconductor substrate and the base layer face each other.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment of the present disclosure.

FIG. 2 is an enlarged view of a region surrounded by two-dot chain line II in FIG. 1.

FIG. 3 is a cross-sectional view taken along line III-III in FIG. 2.

FIG. 4A is a cross-sectional view showing a part of a process of manufacturing the semiconductor device shown in FIG. 3.

FIG. 4B is a view showing a next step of FIG. 4A.

FIG. 4C is a view showing a next step of FIG. 4B.

FIG. 4D is a view showing a next step of FIG. 4C.

FIG. 4E is a view showing a next step of FIG. 4D.

FIG. 4F is a view showing a next step of FIG. 4E.

FIG. 4G is a view showing a next step of FIG. 4F.

FIG. 5 is a schematic cross-sectional view of a semiconductor device according to a second embodiment of the present disclosure, and is a cross-sectional view corresponding to FIG. 3.

FIG. 6 is a schematic cross-sectional view of a semiconductor device according to a comparative example, and is a cross-sectional view corresponding to the cross-sectional view of FIG. 3.

FIG. 7 is a graph showing simulation results of an on-resistance RonA.

FIG. 8 is a graph showing simulation results of a breakdown voltage BVDSS.

FIG. 9 is a schematic cross-sectional view of a semiconductor device according to a third embodiment of the present disclosure, and is a cross-sectional view corresponding to FIG. 3.

FIG. 10 is a schematic cross-sectional view of a semiconductor device according to a fourth embodiment of the present disclosure, and is a cross-sectional view corresponding to FIG. 3.

FIG. 11 is a schematic cross-sectional view of a semiconductor device according to a fifth embodiment of the present disclosure, and is a cross-sectional view corresponding to FIG. 3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of the present disclosure will be described in detail below with reference to the accompanying drawings.

### First Embodiment

### <<Overall Structure of Semiconductor Device A1>>

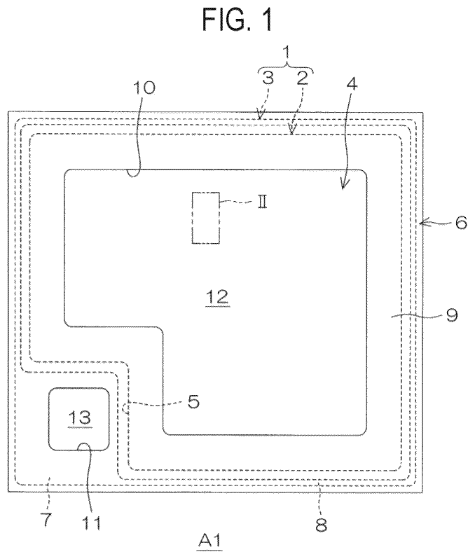

FIG. 1 is a schematic plan view of a semiconductor device A1 according to a first embodiment of the present disclosure.

The semiconductor device A1 has a rectangular shape in a plan view. For example, a MISFET (Metal Insulator Semiconductor Field Effect Transistor) is formed in the semiconductor device A1.

An electrode film 1 is formed on a surface of the semiconductor device A1. The electrode film 1 covers almost the entire surface of the semiconductor device A1. In this embodiment, the electrode film 1 includes a source electrode film 2 and a gate electrode film 3. In this embodiment, the source electrode film 2 is an example of a “first electrode” described in the claims.

The source electrode film 2 is formed to cover an active region 4 of the semiconductor device A1. The active region 4 is, for example, a region in which an element structure (MOS structure) 41 and a super junction structure 42, which will be described later, are formed.

The source electrode film 2 is formed over almost the entire active region 4. A recess 5 is selectively formed in the source electrode film 2 in a plan view. In this embodiment, the recess 5 is formed in one corner of the semiconductor device A1.

The gate electrode film 3 is formed in an outer peripheral region 6 of the semiconductor device A1 that surrounds the active region 4. The gate electrode film 3 includes a pad portion 7 formed in the recess 5 of the source electrode film 2 in a plan view, and a finger portion 8 extending from the pad portion 7 along a side of the semiconductor device A1.

In this embodiment, the finger portion 8 is formed in a closed ring shape surrounding the source electrode film 2. Of course, the finger portion 8 does not need to have a closed ring shape. For example, the finger portion 8 may extend in parallel to two opposing sides (e.g., upper and lower sides in FIG. 1) of the semiconductor device A1, and may terminate at a corner of the semiconductor device A1.

A portion of the electrode film 1 is covered with a passivation film 9 formed on the surface of the semiconductor device A1. The passivation film 9 covers both the source electrode film 2 and the gate electrode film 3, and includes a plurality of openings 10 and 11 that expose portions of the electrode film 1. In FIG. 1, a portion of the source electrode film 2, a portion of the pad portion 7 of the gate electrode film 3, and the finger portion 8 are indicated by broken lines. The portions indicated by the broken lines are the portions covered with the passivation film 9.

A portion of the source electrode film 2 is exposed as a source pad 12 through the first pad opening 10, and a portion (the pad portion 7) of the gate electrode film 3 is exposed as a gate pad 13 through the second pad opening 11. A bonding material such as a bonding wire or the like may be bonded to each of the pads 12 and 13 when packaging the semiconductor device A1.

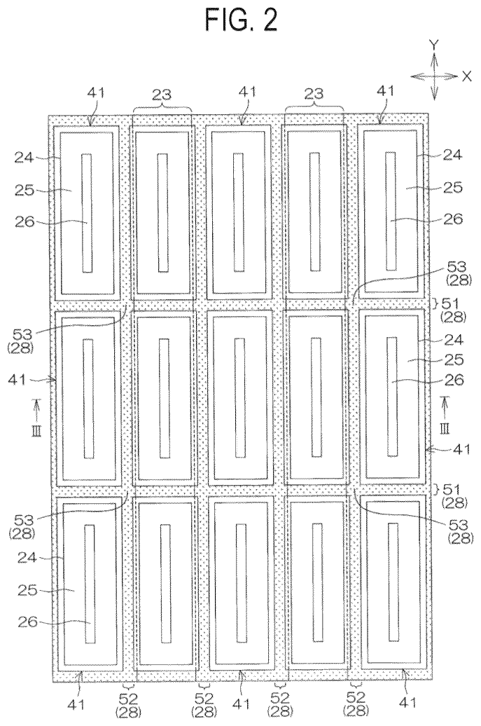

FIG. 2 is an enlarged view of a region surrounded by two-dot chain line II in FIG. 1. In FIG. 2, for the sake of convenience of understanding, a part of a gate electrode 28 is hatched (however, for clarity, a part of the gate electrode 28 facing the body region 24 is not hatched).

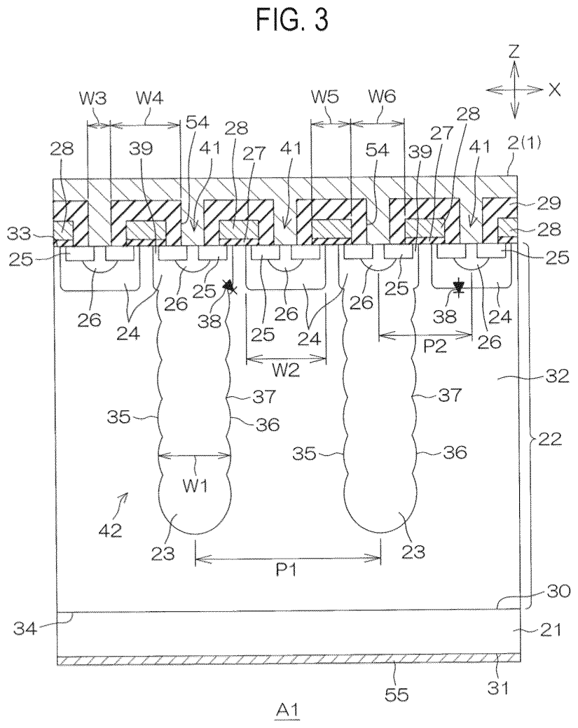

FIG. 3 is a cross-sectional view taken along line III-III in FIG. 2. For the sake of convenience of description, three mutually perpendicular directions are defined as an X direction, a Y direction, and a Z direction. The Z direction is a thickness direction of the semiconductor device A1. The X direction is a left-right direction in a plan view of the semiconductor device A1 (see FIG. 2). The Y direction is an up-down direction in a plan view of the semiconductor device A1 (see FIG. 2).

The semiconductor device A1 may include a semiconductor substrate 21, an epitaxial layer 22, a column layer 23, a body region 24, a source region 25, a body contact region 26, a gate insulating film 27, a gate electrode 28, and an interlayer insulating film 29. In this embodiment, the epitaxial layer 22 and the source region 25 are examples of a “semiconductor layer” and a “first region,” respectively, which are recited in the claims.

In this embodiment, the semiconductor substrate 21 may be an n+-type semiconductor substrate (e.g., a silicon substrate). In addition, the semiconductor substrate 21 may be a substrate commonly used for transistors, such as a SiC substrate, a GaN substrate, or the like. The n+-type semiconductor substrate 21 may be a semiconductor substrate in which crystals are grown while doping with an n-type impurity.

As the n-type impurity, P (phosphorus), As (arsenic), Sb (antimony), or the like may be applied. Further, an impurity concentration of the n+-type semiconductor substrate 21 may be, for example, about 1.0×10¹⁸ cm⁻³ to 5.0×10²⁰ cm⁻³. The semiconductor substrate 21 includes a first surface 30 and a second surface 31 on an opposite side of the first surface 30.

The epitaxial layer 22 may be, for example, an n-type layer epitaxially grown on the n+-type semiconductor substrate 21 while implanting an n-type impurity. Examples of the n-type impurity are as described above. Further, an impurity concentration of the n-type epitaxial layer 22 may be lower than that of the n+-type semiconductor substrate 21, for example, about 1.0×10¹⁵ cm⁻³ to 1.0×10¹⁷ cm⁻³. Furthermore, the n-type region in the epitaxial layer 22 may be referred to as an n-type drift region 32.

The epitaxial layer 22 (drift region 32) includes a first surface 33 and a second surface 34 on an opposite side of the first surface 33. The first surface 33 is a surface on which the element structure 41 to be described later is formed, and may also be referred to as an element main surface. The second surface 34 is a surface in contact with the first surface 30 of the semiconductor substrate 21.

The column layer 23 may be a p-type semiconductor layer formed by ion-implanting a p-type impurity into the epitaxial layer 22. As the p-type impurity, B (boron), A1 (aluminum), Ga (gallium), or the like may be used. Further, an impurity concentration of the column layer 23 may be, for example, about 1.0×10¹⁵ cm⁻³ to 1.0×10¹⁸ cm⁻³.

As shown in FIGS. 2 and 3, a plurality of column layers 23 are formed in the epitaxial layer 22. As shown in FIG. 3, each column layer 23 extends in the Z direction and, for example, extends from an upper portion of the epitaxial layer 22 beyond a center of the epitaxial layer 22 in the Z-direction.

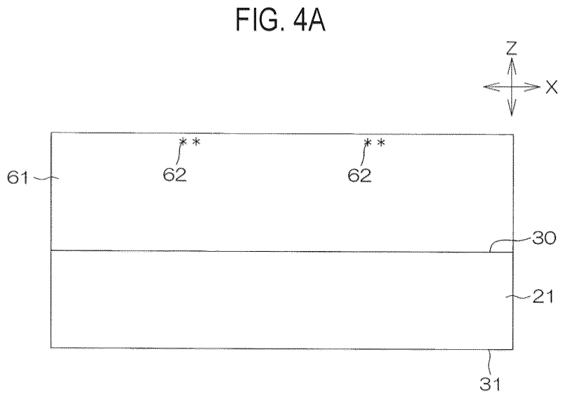

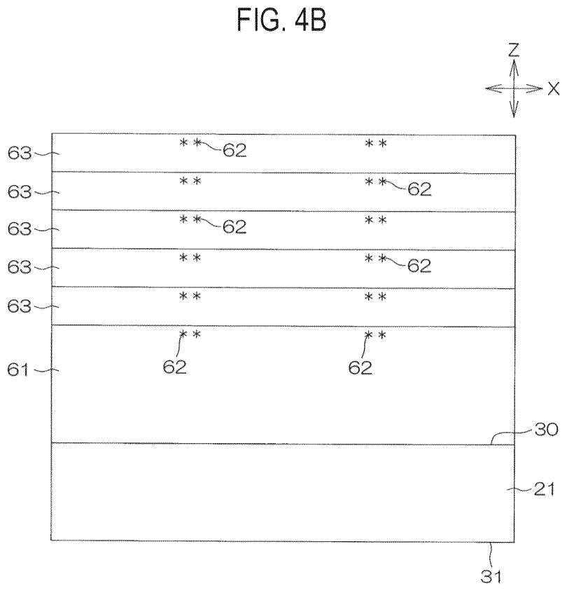

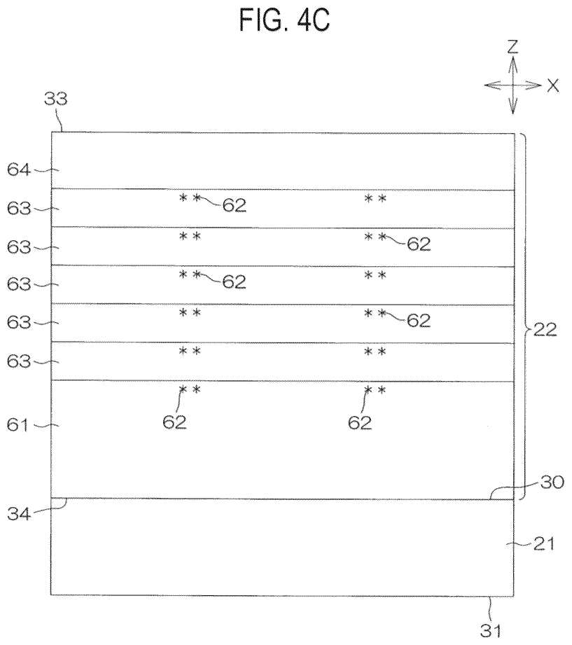

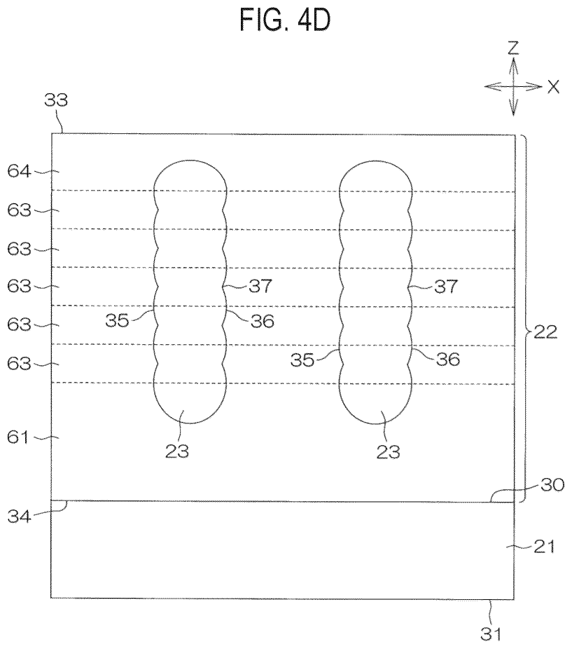

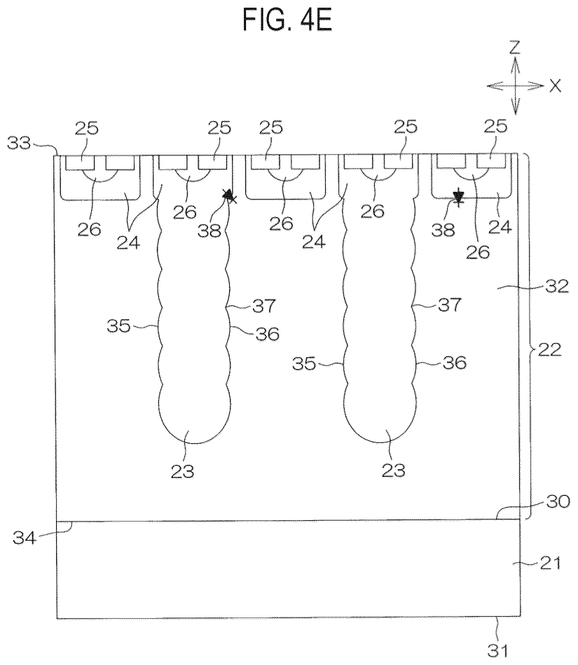

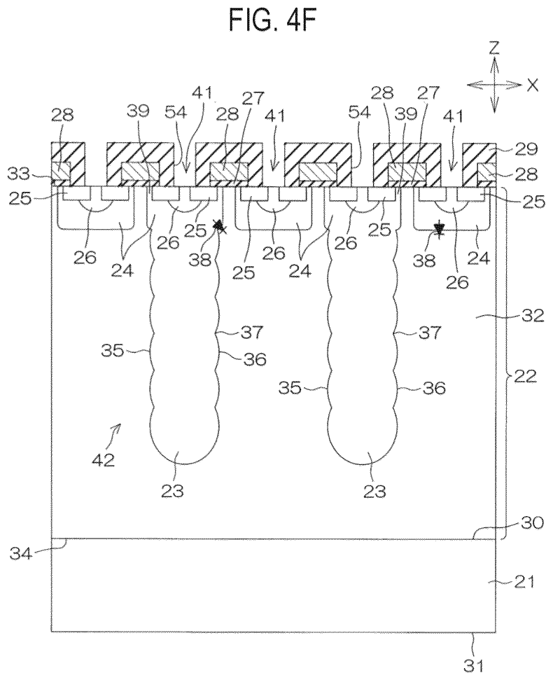

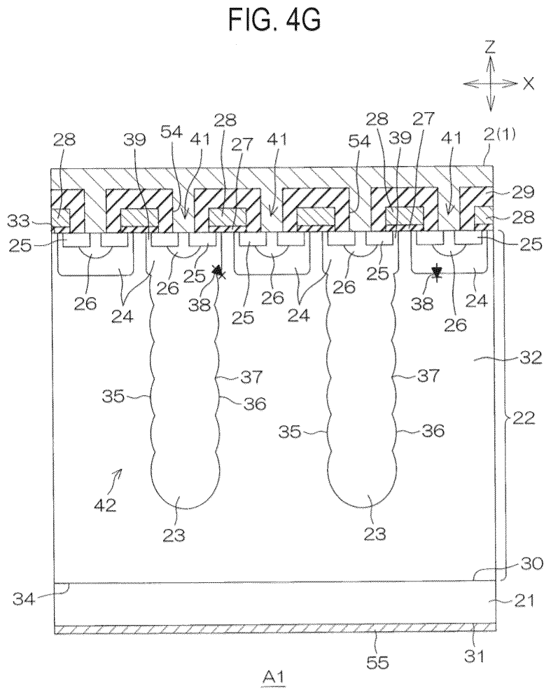

As shown in FIG. 2, each column layer 23 has a band shape extending in the Y direction in a plan view. Further, a side surface 35 of each column layer 23 extending along the Z direction is a periodically undulating concave and convex surface including convex portions 36 and concave portions 37 repeatedly arranged along the Z direction. The number of convex portions 36 and concave portions 37 is usually almost the same as the number of steps of an n-type semiconductor layer 63 (see FIGS. 4A and 4B), which will be described later. An X-direction width of the column layer 23 (an X-direction length of the convex portions 36) may be about 2 μm to 3 μm.

As shown in FIGS. 2 and 3, the plurality of column layers 23 are arranged at equal intervals in the X direction. In other words, the plurality of column layers 23 are formed in a stripe shape in a plan view.

An arrangement interval of the column layers 23 in the X direction is referred to as an inter-column layer pitch P1. The inter-column layer pitch P1 is a distance between width centers of two column layers 23 adjacent in the X direction. Specifically, the inter-column layer pitch P1 is the distance from the width center (length center in the X direction) of one of the two column layers 23 adjacent in the X direction to the width center (length center in the X direction) of the other column layer 23. The inter-column layer pitch P1 is 7 μm in this embodiment.

The super junction structure 42 is formed within the epitaxial layer 22 by forming the plurality of column layers 23 within the epitaxial layer 22. In other words, the super junction structure 42 is formed by alternately and repeatedly arranging the p-type column layers 23 and the n-type epitaxial layers 22 in a direction (X direction in this embodiment) perpendicular to the thickness direction (Z direction) of the epitaxial layers 22.

A plurality of body regions 24 are formed in a surface of the epitaxial layer 22. In this embodiment, the body region 24 has a rectangular shape elongated in the Y direction in a plan view. In this embodiment, the body regions 24 are arranged in a matrix at intervals in the X direction and the Y direction in a plan view. An arrangement interval of the body regions 24 in the X direction is referred to as an inter-body region pitch P2.

The inter-body region pitch P2 is a distance between width centers of two body regions 24 adjacent to each other in the X direction. Specifically, the inter-body region pitch P2 is the distance from the width center (length center in the X direction) of one of the two body regions 24 adjacent to each other in the X direction to the width center (length center in the X direction) of the other body region 24.

The inter-body region pitch P2 is different from the inter-column layer pitch P1. In the first embodiment, the inter-body region pitch P2 is shorter than the inter-column layer pitch P1. In the first embodiment, the inter-body region pitch P2 is half the inter-column layer pitch P1. In other words, the ratio P2/P1 of the inter-body region pitch P2 to the inter-column layer pitch P1 is ½.

More specifically, in the first embodiment, the inter-column layer pitch P1 is 7 μm, whereas the inter-body region pitch P2 is 3.5 μm. When the inter-body region pitch P2 is shorter than the inter-column layer pitch P1, the ratio P2/P1 of the inter-body region pitch P2 to the inter-column layer pitch P1 may be a value other than ½.

The body regions 24 may be p-type semiconductor layers formed by ion-implanting a p-type impurity into the n-type epitaxial layer 22. Examples of the p-type impurity are as described above. Further, an impurity concentration of the body regions 24 is, for example, about 1.0×10¹⁵ cm⁻³ to 1.0×10¹⁹ cm⁻³, and may be the same as the impurity concentration of the column layers 23.

In the first embodiment, an X-direction width W2 of the body region 24 (body region width) is slightly larger than an X-direction width W1 of the column layer 23 (column layer width). In other words, the X-direction width W1 of the column layer 23 is slightly smaller than the X-direction width W2 of the body region 24.

The X-direction width W2 of the body region 24 may be smaller than the X-direction width W1 of the column layer 23, or may be equal to the X-direction width W1 of the column layer 23.

As shown in FIG. 3, each body region 24 forms a parasitic diode 38 (body diode) at an interface with the drift region 32 (pn junction surface).

The source region 25 is formed in an inner region of each body region 24. The source region 25 is selectively formed in a surface of the body region 24 in the inner region. The source region 25 may be formed by selectively ion-implanting an n-type impurity into the body region 24. Examples of the n-type impurity are as described above. Further, an impurity concentration of the source region 25 may be higher than that of the drift region 32, and may be, for example, about 1.0×10¹⁸ cm⁻³ to 5.0×10²⁰ cm⁻³.

The source region 25 has a rectangular ring shape in a plan view, and is spaced inward by a predetermined distance from a peripheral edge of the body region 24 (from a boundary between the body region 24 and the drift region 32). As a result, in the surface of the epitaxial layer 22 including the drift region 32, the body region 24, and the like, the surface of the body region 24 is interposed between the source region 25 and the drift region 32. This interposed surface is a channel region 39 in which a channel is formed when an appropriate voltage is applied to the gate electrode 28.

The body contact region 26 has a rectangular shape elongated in the Y direction in a plan view, and is selectively formed in the surface portion of the body region 24. The body contact region 26 extends toward the second surface 34 of the epitaxial layer 22 to pass through the source region 25 and reach the body region 24. The body contact region 26 may be formed by selectively ion-implanting a p-type impurity into the body region 24. Examples of the p-type impurity are as described above. Further, an impurity concentration of the body contact region 26 may be higher than that of the body region 24, and may be, for example, about 5.0×10¹⁷ cm⁻³ to 1.0×10¹⁹ cm⁻³.

The body region 24, the source region 25, and the body contact region 26 constitute a MISFET element structure 41 (unit cell).

In this embodiment, in a plan view, the column layers 23 are arranged every other row for a plurality of body region rows arranged side by side in the X direction. In the body region rows in which the column layers 23 are arranged, lower portions of the plurality of body regions 24 in which the column layers 23 are arranged are connected to upper portions of the column layers 23. That is, the column layers 23 include a column layer 23 disposed below the body region 24 to be in contact with the body region 24.

The gate insulating film 27 may be made of, for example, a silicon oxide film, a silicon nitride film, a silicon oxynitride film, a hafnium oxide film, an alumina film, a tantalum oxide film, or the like. Further, the gate electrode 28 may be made of polysilicon formed by implanting an impurity. When the gate insulating film 27 is made of a silicon oxide film, the MISFET may be referred to as a MOSFET (Metal Oxide Semiconductor Field Effect Transistor).

The gate insulating film 27 covers at least the surface of the body region 24. In this embodiment, the gate insulating film 27 covers a portion of a surface of the source region 25, and surfaces of the channel region 39 and the drift region 32. More specifically, the gate insulating film 27 is formed in a pattern having an opening in a portion of the body contact region 26 of each element structure 41 and a portion of the source region 25 connected to the body contact region 26.

The gate insulating film 27 is interposed between the gate electrode 28 and the epitaxial layer 22. Thus, the gate electrode 28 faces the channel region 39 with the gate insulating film 27 interposed therebetween. The gate electrode 28 is formed in substantially the same pattern as the gate insulating film 27, thereby forming a planar gate structure. In addition, the gate insulating film 27 may have a thickness of, for example, 300 Å to 700 Å.

Furthermore, in this embodiment, the gate electrode 28 is formed in a lattice pattern, as shown in FIGS. 2 and 3. More specifically, the gate electrode 28 includes a first portion 51 extending in the X direction, a second portion 52 extending in the Y direction orthogonal to the X direction, and an intersection portion 53 where the first portion 51 and the second portion 52 intersect.

The interlayer insulating film 29 is formed on the epitaxial layer 22. The interlayer insulating film 29 covers the gate electrode 28. The interlayer insulating film 29 may be made of an insulating material such as a silicon oxide film, a silicon nitride film, TEOS (tetraethoxysilane), or the like.

A contact hole 54 is formed in the interlayer insulating film 29 to expose the body contact region 26 and the source region 25 of the MISFET. The contact hole 54 penetrates the interlayer insulating film 29 and the gate insulating film 27.

The aforementioned electrode film 1 is formed on the interlayer insulating film 29. The electrode film 1 may be made of aluminum or other metal. In FIG. 3, the source electrode film 2 is shown. The source electrode film 2 may be simply referred to as a source electrode.

The source electrode film 2 is connected to the body contact region 26 and the source region 25 within the contact hole 54, as shown in FIG. 2. The gate electrode film 3 is connected to the gate electrode 28 at a position not shown.

A drain electrode 55 is formed on the second surface 31 of the semiconductor substrate 21. The drain electrode 55 may be made of aluminum or other metal. The drain electrode 55 is electrically connected to the drift region 32 via the semiconductor substrate 21.

In this embodiment, an X-direction length (contact hole width) W3 of the contact hole 54 is 0.7 μm, and a gap interval (contact hole gap interval) W4 between two contact holes 54 adjacent to each other in the X direction is 2.8 μm. Further, in this embodiment, an X-direction length (gate electrode width) W5 of the second portion 52 of the gate electrode 28 is 1.8 μm, and a gap interval (gate electrode gap interval) W6 between two second portions 52 adjacent to each other in the X direction is 1.7 μm.

### <<Method of Manufacturing Semiconductor Device A1>>

FIGS. 4A to 4G are views showing processes of manufacturing the semiconductor device A1 in the order of processes.

Referring first to FIG. 4A, in order to manufacture the semiconductor device A1, an initial base layer 61 is formed on a semiconductor substrate 16 by epitaxial growth. Next, a p-type impurity 62 is selectively implanted into a surface of the initial base layer 61 at positions where column layers 23 are to be formed.

Referring next to FIG. 4B, a plurality of n-type semiconductor layers 63 are stacked on the initial base layer 61 by multi-epitaxial growth that repeats a process of forming an n-type semiconductor layer 63 while selectively implanting a p-type impurity 62 into the positions where the column layers 23 are to be formed.

Referring further to FIG. 4C, an uppermost n-type semiconductor layer 64 is stacked without implanting the p-type impurity. Thus, the plurality of n-type semiconductor layers 63 and 64 and the initial base layer 61 are integrated to form an epitaxial layer 22 (drift region 32).

Referring next to FIG. 4D, by performing an annealing process (at 1,000 degrees C. to 1,200 degrees C.), the p-type impurity in the initial base layer 61 and the plurality of n-type semiconductor layers 63 and 64 are driven and diffused. As a result, the column layers 23 are formed within the epitaxial layer 22.

Referring next to FIG. 4E, a body region 24 is formed by selectively implanting a p-type impurity into a surface of the epitaxial layer 22. Among the plurality of body regions 24, the body region 24 disposed directly above the column layer 23 is connected to the column layer 23.

Next, a source region 25 is formed by selectively implanting an n-type impurity into a surface of the body region 24. Next, a body contact region 26 is formed by selectively implanting a p-type impurity into the surface of the body region 24.

Referring next to FIG. 4F, a gate insulating film 27 is formed on the epitaxial layer 22. The gate insulating film 27 may be formed by growing an oxide film through thermal oxidation of a semiconductor crystal surface and then patterning the oxide film.

Next, a gate electrode 28 is formed on the gate insulating film 27. The gate electrode 28 may be formed, for example, by forming a polysilicon film doped with an impurity over an entire surface and then selectively etching the polysilicon film by photolithography. Next, an interlayer insulating film 29 is formed to cover the gate electrode 28. Next, a contact hole 54 is formed in the interlayer insulating film 29 by photolithography.

Referring next to FIG. 4G, a semiconductor substrate 21 is ground and planarized from a second surface 31 side. The amount of grinding is not particularly limited, but it is preferable that the semiconductor substrate 21 after grinding has a thickness of, for example, 90 μm to 310 μm. Next, a source electrode film 2 and a gate electrode film 3 (not shown) are formed on the interlayer insulating film 29. Next, a passivation film 9 (not shown) is formed to cover the source electrode film 2 and the gate electrode film 3. Next, pad openings 10 and 11 (not shown) are formed in the passivation film 9 by photolithography.

Thereafter, a drain electrode 55 is formed on the second surface 31 of the semiconductor substrate 16, thereby obtaining the above-described semiconductor device A1.

### «Operation and Effects of Semiconductor Device A1»

First, an operation of the MISFET of the semiconductor device A1 will be described. When the drain electrode 55 is connected to a higher potential than the source electrode film 2 and a control voltage equal to or higher than a threshold voltage is applied to the gate electrode 28, an inversion layer (channel) is formed in the body region 24 (channel region 39). Thus, a current path is formed between the source region 25 and the drift region 32. If no control voltage is applied to the gate electrode 28, no inversion layer is generated and the current path between the source and drain is cut off.

In this embodiment, the inter-column layer pitch P1 and the inter-body region pitch P2 are different. The inter-column layer pitch P1 has a large influence on the breakdown voltage characteristics of the MISFET. On the other hand, the inter-body region pitch P2 has a large influence on the on-resistance characteristics and switching characteristics (gate layer charge amount Qg) of the MISFET.

The reason that the inter-body region pitch P2 has a large influence on the switching characteristics is as follows. A gate-drain capacitance is changed depending on the inter-body region pitch P2. A change in the gate-drain capacitance leads to a change in a Miller capacitance Qgd and a change in a switching speed. Specifically, the smaller the gate-drain capacitance, the smaller the Miller capacitance Qgd. This reduces a gate layer charge amount Qg and increases the switching speed.

According to this embodiment, by adjusting the inter-column layer pitch P1, it is possible to mainly adjust the breakdown voltage characteristics, and by adjusting the inter-body region pitch P2, it is possible to adjust the on-resistance characteristics and switching characteristics.

### Second Embodiment

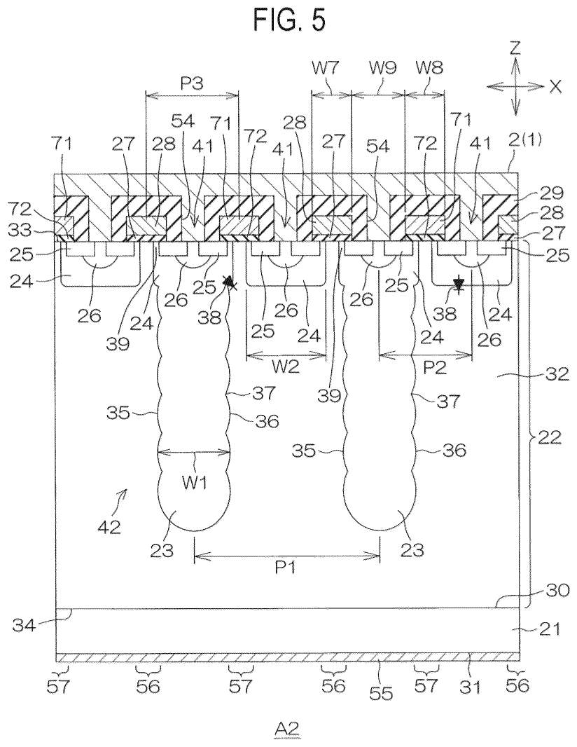

FIG. 5 is a schematic cross-sectional view of a semiconductor device A2 according to a second embodiment of the present disclosure, and is a cross-sectional view corresponding to FIG. 3. In FIG. 5, parts corresponding to those shown in FIG. 3 are designated by the same reference numerals as in FIG. 3.

In the semiconductor device A2 according to the second embodiment, an inter-column layer pitch P1 and an inter-body region pitch P2 are respectively the same as the inter-column layer pitch P1 and the inter-body region pitch P2 in the semiconductor device A1 according to the first embodiment.

In the semiconductor device A2 according to the second embodiment, a portion of the gate electrode 28 of the semiconductor device A1 according to the first embodiment is replaced with a dummy gate electrode 71. Therefore, the semiconductor device A2 according to the second embodiment includes a plurality of gate electrodes 28 and a plurality of dummy gate electrodes 71. The dummy gate electrodes 71 may be made of polysilicon formed by implanting an impurity.

Each gate electrode 28 and each dummy gate electrode 71 have a band shape elongated in the Y direction in a plan view. In this embodiment, an X-direction length W7 of the gate electrode 28 (gate electrode width) and an X-direction length W8 of the dummy gate electrode 71 (dummy electrode width) are the same. The gate electrode width W7 and the dummy electrode width W8 are the same as the width W5 of the second portion 52 of the gate electrode 28 of the semiconductor device A1 according to the first embodiment.

The gate electrodes 28 and the dummy gate electrodes 71 are alternately arranged at equal intervals in the X direction. In other words, a first row 56 in which the gate electrodes 28 are formed along the Y direction and a second row 57 in which the dummy gate electrodes 71 are formed along the Y direction are alternately arranged at equal intervals in the X direction. In other words, the gate electrodes 28 and the dummy gate electrodes 71 are respectively formed in a stripe shape extending in the Y direction at intervals in the X direction in a plan view.

The first row 56 passes between every other two adjacent body regions 24 in the X direction. The second row 57 passes between two adjacent body regions 24 in a region between two first rows 56 adjacent to each other in the X direction. Therefore, if the gate electrodes 28 and the dummy gate electrodes 71 are collectively referred to as internal electrodes 28 and 71 and if an arrangement interval of the internal electrodes 28 and 71 in the X direction is referred to as an inter-internal electrode pitch P3, then the inter-internal electrode pitch P3 is equal to the inter-body region pitch P2.

The inter-internal electrode pitch P3 is a distance between width centers of two internal electrodes 28 and 71 adjacent to each other in the X direction. Specifically, the inter-internal electrode pitch P3 is a distance from the width center (X-direction length center) of one of the two internal electrodes 28 and 71 adjacent to each other in the X direction to the width center (X-direction length center) of the other internal electrode 71. The inter-internal electrode pitch P3 is equal to the inter-body region pitch P2. A gap interval W9 between the two internal electrodes 28 and 71 adjacent to each other in the X direction is equal to the gate electrode gap interval W6 of the semiconductor device A1 according to the first embodiment.

A gate insulating film 27 is interposed between the gate electrode 28 and an epitaxial layer 22. An insulating film 72 is interposed between the dummy gate electrode 71 and the epitaxial layer 22. The insulating film 72 may be made of, for example, a silicon oxide film, a silicon nitride film, a silicon oxynitride film, a hafnium oxide film, an alumina film, a tantalum oxide film, or the like. The insulating film 72 may be made of the same material as the gate insulating film 27.

The gate electrode 28 is electrically connected to a gate electrode film 3 at a position not shown. The dummy gate electrode 71 is electrically connected to a source electrode film 2 at a position not shown.

In the second embodiment, the gate insulating film 27 is an example of a “first insulating film” recited in the claims, and the insulating film 72 is an example of a “second insulating film” recited in the claims.

The second embodiment has the following effects in addition to the effects of the first embodiment. When a forward voltage is applied to a parasitic diode 38, the parasitic diode 38 is in an on-state, and when a reverse voltage is applied to the parasitic diode 38, the parasitic diode 38 is in an off-state. When the parasitic diode is turned off, a reverse recovery phenomenon occurs. A resultant current is a reverse recovery current. Due to the movement of carriers, a depletion layer extends from the pn junction, and the parasitic diode is turned off. When the change in the reverse recovery current is large, oscillation (ringing) may occur until the reverse recovery current converges to zero.

According to the second embodiment, the source electrode film 2 is connected to the dummy gate electrode 71. Therefore, when the parasitic diode 38 is turned off, a density of holes in an n-type drift region 32 on a first surface 33 of the epitaxial layer 22 is decreased locally. As a result, it becomes easy for the depletion layer to extend on the first surface 33 of the epitaxial layer 22, thereby making it possible to speed up timing of extension of the depletion layer. Therefore, the depletion layer can be caused to gradually extend from the first surface 33 of the epitaxial layer 22. As a result, when the parasitic diode 38 is turned off, a reverse current flowing through the parasitic diode 38 can be slowly returned to zero, so that a reverse recovery characteristic of the parasitic diode 38 can be brought close to a soft recovery characteristic.

### Comparison of First Embodiment and Second Embodiment with Comparative Example

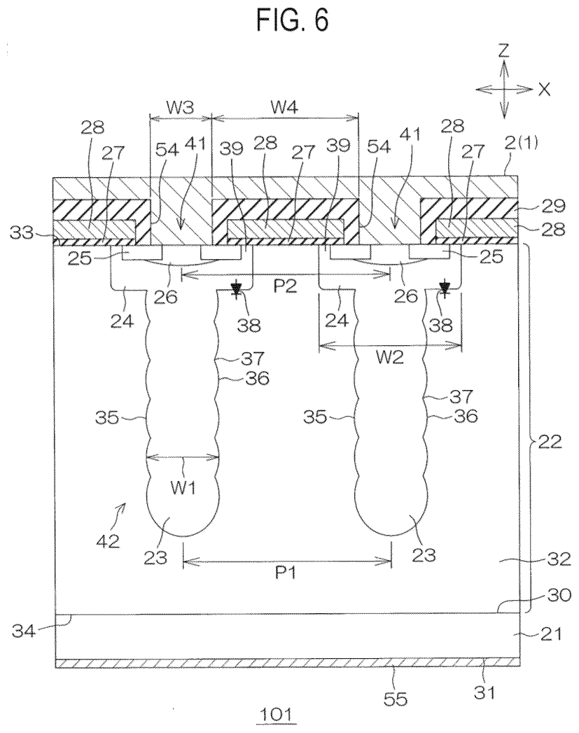

FIG. 6 is a cross-sectional view of a semiconductor device 101 according to a comparative example, and is a cross-sectional view corresponding to the cross-sectional view of FIG. 3. In FIG. 6, parts corresponding to those in FIG. 3 are designated by the same reference numerals as in FIG. 3.

In the following, the semiconductor device A1 according to the first embodiment is simply referred to as the first embodiment, the semiconductor device A2 according to the second embodiment is simply referred to as the second embodiment, and the semiconductor device 101 according to the comparative example is simply referred to as the comparative example.

The comparative example includes almost the same configuration as the first embodiment. The comparative example differs from the first embodiment in that an inter-body region pitch P2 is equal to an inter-column layer pitch P1 and that a body region width W2 is larger than the body region width W2 of the first embodiment.

In the comparative example, since the inter-body region pitch P2 and the inter-column layer pitch P1 are equal to each other, the ratio P2/P1 of the inter-body region pitch P2 to the inter-column layer pitch P1 is 1. The inter-column layer pitch P1 in the comparative example is equal to the inter-column layer pitch P1 in the first embodiment. Therefore, the inter-column layer pitch P1 and the inter-body region pitch P2 in the comparative example are 7 μm. As described above, in the first embodiment (second embodiment), the inter-body region pitch P2 is 3.5 μm.

The body region width W2 in the comparative example is approximately 1.8 times the body region width W2 in the first embodiment. The column layer width W1 in the comparative example is equal to the column layer width W1 in the first embodiment.

In this comparative example, an X-direction length W3 of the contact hole 54 (contact hole width) is 1.7 μm, and a gap interval W4 between two contact holes 54 adjacent to each other in the X direction (contact hole gap interval) is 5.3 μm.

For each of the first embodiment, the second embodiment, and the comparative example, the on-resistance RonA [Ωmm²] and the breakdown voltage BVDSS [V] were calculated by simulation when the p-type impurity concentration of the column layers 23 is changed.

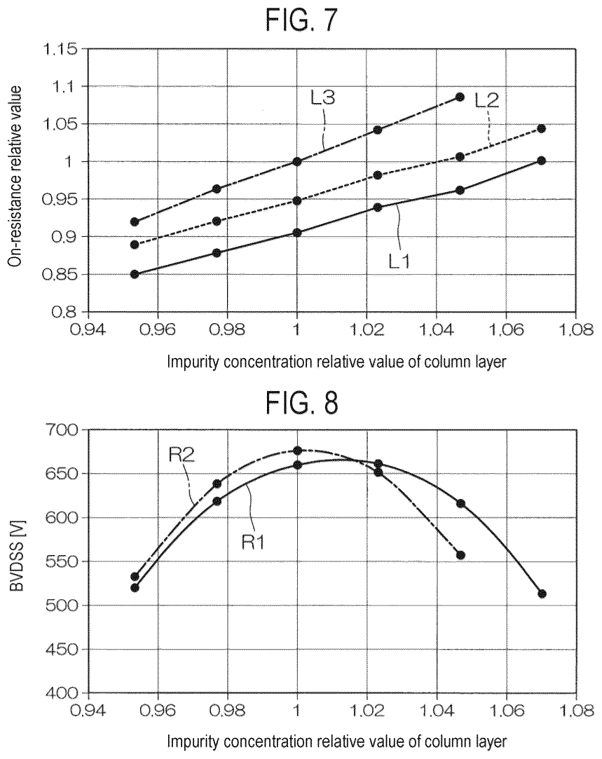

FIG. 7 is a graph showing simulation results of the on-resistance RonA. A horizontal axis in FIG. 7 indicates an impurity concentration relative value when a preset reference value of a p-type impurity concentration of the column layers 23 (hereinafter referred to as “impurity concentration reference value”) [cm⁻³] is set as a relative value of 1. In other words, the horizontal axis in FIG. 7 indicates a value obtained by dividing an actual impurity concentration by the impurity concentration reference value.

A vertical axis in FIG. 7 indicates an on-resistance relative value when an on-resistance [Ωmm²] relative to an impurity concentration reference value (hereinafter referred to as the “on-resistance reference value”) in the comparative example is set as a relative value of 1. In other words, the vertical axis in FIG. 7 indicates a value obtained by dividing an actual on-resistance by the on-resistance reference value.

Broken lines L1, L2, and L3 in FIG. 7 represent simulation results of the on-resistance RonA for the first embodiment, the second embodiment, and the comparative example, respectively.

It can be seen from FIG. 7 that the on-resistance RonA is smaller in the first embodiment and the second embodiment than in the comparative example. Further, it can be seen that the on-resistance RonA is smaller in the first embodiment than in the second embodiment.

The reason that the on-resistance RonA in the first embodiment is smaller than that in the comparative example may be considered as follows. The inter-column layer pitch P1 in the first embodiment is the same as the inter-column layer pitch P1 in the comparative example, but the inter-body region pitch P2 in the first embodiment is shorter than the inter-body region pitch P2 in the comparative example. Thus, a total area of the channel region 39 in the first embodiment becomes larger than a total area of the channel region 39 in the comparative example. Therefore, the on-resistance RonA in the first embodiment become smaller than the on-resistance RonA in the comparative example. More specifically, in the first embodiment, the inter-body region pitch P2 is ½ of the inter-column layer pitch P1. Therefore, the total area of the channel region 39 is approximately twice that in the comparative example. As a result, it is considered that the on-resistance RonA is smaller than that in the comparative example.

Also in the second embodiment, since the inter-body region pitch P2 is ½ of the inter-column layer pitch P1, the total area of the channel region 39 is apparently the same as that in the first embodiment. However, in the second embodiment, since a portion of the gate electrode 28 in the first embodiment is replaced with the dummy gate electrode 71, the substantial channel area is smaller than the total area of the channel region 39 in the first embodiment. As a result, it is considered that the on-resistance RonA is smaller than that in the first embodiment.

In the first embodiment, the gate-drain capacitance is larger than that in the comparative example. Therefore, the switching speed is slower than that in the comparative example. On the other hand, in the second embodiment, a portion of the gate electrode 28 in the first embodiment is replaced with the dummy gate electrode 71, and the gate electrode 28 is formed in a stripe shape instead of a lattice shape in a plan view. Therefore, the gate-drain capacitance becomes smaller than that in the first embodiment and that in the comparative example. As a result, switching becomes faster in comparison to the first embodiment and in the comparative example.

FIG. 8 is a graph showing simulation results of the breakdown voltage BVDSS. A horizontal axis in FIG. 8 indicates an impurity concentration relative value when a preset reference value (impurity concentration reference value) [cm⁻³] of a p-type impurity concentration of the column layers 23 is set as a relative value of 1. The vertical axis in FIG. 8 indicates the breakdown voltage BVDSS [V].

In FIG. 8, a curve R1 is a graph showing simulation results of the breakdown voltage BVDSS in the first embodiment and the second embodiment. A curve R2 is a graph showing simulation results of the breakdown voltage BVDSS in the comparative example.

It can be seen from FIG. 8 that the breakdown voltage BVDSS in the first embodiment and the second embodiment is not much different from that in the comparative example. In other words, it can be seen that even if the inter-body region pitch P2 is smaller than the inter-column layer pitch P1, a degree of influence on the breakdown voltage characteristics is small.

### Third Embodiment

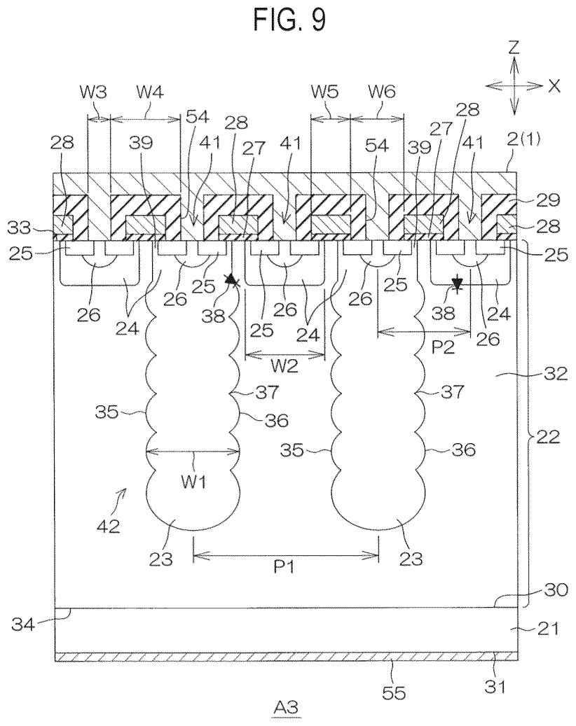

FIG. 9 is a schematic cross-sectional view of a semiconductor device A3 according to a third embodiment of the present disclosure, and is a cross-sectional view corresponding to FIG. 3. In FIG. 8, parts corresponding to those in FIG. 3 are designated by the same reference numerals as in FIG. 3.

The semiconductor device A3 according to the third embodiment has substantially the same configuration as the first embodiment.

The semiconductor device A3 according to the third embodiment differs from the first embodiment in that an X-direction width W1 of the column layers 23 (an X-direction length of the convex portions 36) is larger than an X-direction width W2 of the body region 24. In the semiconductor device A3 according to the third embodiment, the X-direction width W1 of the column layers 23 is, for example, about 2 μm to 2.5 μm.

Lengths of P1, P2, W3, W4, W5, and W6 in FIG. 9 are equal to the lengths of P1, P2, W3, W4, W5, and W6 in FIG. 3, respectively.

### Fourth Embodiment

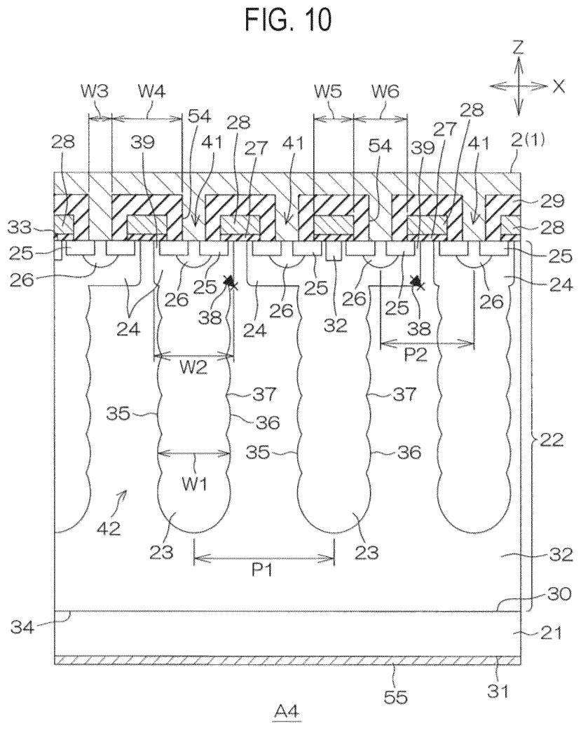

FIG. 10 is a schematic cross-sectional view of a semiconductor device A4 according to a fourth embodiment of the present disclosure, and is a cross-sectional view corresponding to FIG. 3. In FIG. 10, parts corresponding to those in FIG. 3 are designated by the same reference numerals as in FIG. 3.

The semiconductor device A4 according to the fourth embodiment has substantially the same configuration as the first embodiment.

The semiconductor device A4 according to the fourth embodiment is different from the semiconductor device A1 according to the first embodiment in terms of a ratio P2/P1 of an inter-body region pitch P2 to an inter-column layer pitch P1.

In the example of FIG. 10, the ratio P2/P1 of the inter-body region pitch P2 to the inter-column layer pitch P1 is ⅔. In the example of FIG. 10, the inter-column layer pitch P1 is 5.25 μm, and the inter-body region pitch P2 is 3.5 μm.

Lengths of W1, W2, W3, W4, W5, and W6 in FIG. 10 are equal to the lengths of W1, W2, W3, W4, W5, and W6 in FIG. 3, respectively.

### Fifth Embodiment

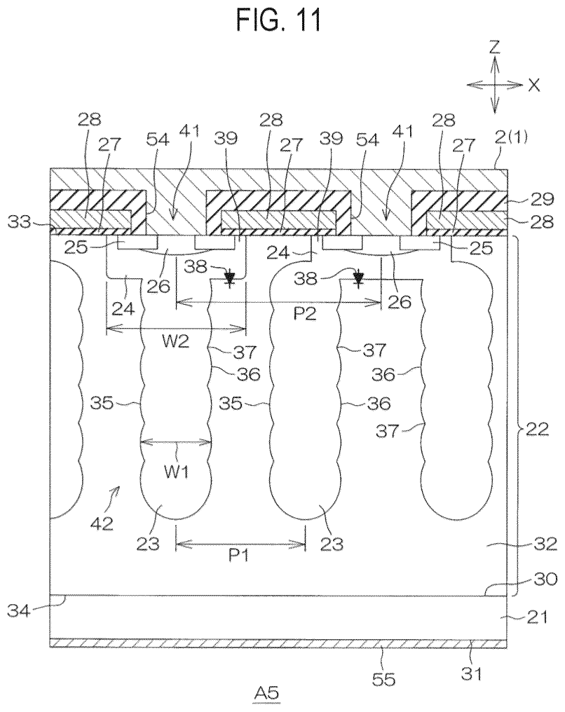

FIG. 11 is a schematic cross-sectional view of a semiconductor device A5 according to a fifth embodiment of the present disclosure, and is a cross-sectional view corresponding to FIG. 3. In FIG. 11, parts corresponding to those in FIG. 3 are designated by the same reference numerals as in FIG. 3.

The semiconductor device A5 according to the fifth embodiment has substantially the same configuration as the first embodiment.

The semiconductor device A5 according to the fifth embodiment differs from the semiconductor device A1 according to the first embodiment in that an inter-body region pitch P2 is larger than an inter-column layer pitch P1. In the example of FIG. 11, the inter-column layer pitch P1 is 4.2 μm, and the inter-body region pitch P2 is 7 μm.

In the semiconductor device A5 according to the fifth embodiment, the body region width W2 is larger than the column layer width W1. However, the body region width W2 may be smaller than the column layer width W1, and the body region width W2 may be equal to the column layer width W1.

Although the embodiments of the present disclosure have been described above, the present disclosure may also be implemented in other forms.

For example, a configuration may be adopted in which a conductivity type of each semiconductor portion of the semiconductor devices A1 to A5 is reversed. For example, in semiconductor devices A1 to A5, the p-type portion may be n-type, and the n-type portion may be p-type.

Although the embodiments of the present disclosure have been described above in detail, these embodiments are merely specific examples used to clarify the technical content of the present disclosure. The present disclosure should not be construed as being limited to these specific examples. The scope of the present disclosure is limited only by the appended claims.

The features described below as supplementary notes can be extracted from the description in the specification and the drawings.

### [Supplementary Note 1-1]

A semiconductor device, comprising:
a semiconductor layer (22) having a first conductivity type and including a first surface (33) and a second surface (34) on an opposite side of the first surface (33);
a plurality of element structures (41) formed in the first surface (33) of the semiconductor layer (22) at equal intervals in one direction; and
a super junction structure (42) formed in the semiconductor layer, wherein each of the plurality of element structures (41) includes:
   a body region (24) having a second conductivity type and formed in the first surface (33) of the semiconductor layer (22); and
   a first region (25) having the first conductivity type and formed in a surface of the body region (24),
wherein the super junction structure (42) includes a plurality of column layers (23) having the second conductivity type formed in the semiconductor layer at equal intervals in the one direction and extending in a thickness direction of the semiconductor layer (22), and
wherein an inter-body region pitch (P2), which is an arrangement interval of the body regions (24) of the plurality of element structures (41) in the one direction, is different from an inter-column layer pitch (P1), which is an arrangement interval of the plurality of column layers (23) in the one direction.

### [Supplementary Note 1-2]

The semiconductor device of Supplementary Note 1-1, wherein the inter-body region pitch (P2) is shorter than the inter-column layer pitch (P1).

### [Supplementary Note 1-3]

The semiconductor device of Supplementary Note 1-1, wherein the inter-body region pitch (P2) is longer than the inter-column layer pitch (P1).

### [Supplementary Note 1-4]

The semiconductor device of any one of Supplementary Note 1-1 to Supplementary Note 1-3, wherein the plurality of column layers (23) include a column layer (23) disposed below the body region (24) to be in contact with the body region (24).

### [Supplementary Note 1-5]

The semiconductor device of any one of Supplementary Note 1-1 to Supplementary Note 1-4, wherein a column layer width (W1), which is a length of a column layer (23) of the plurality of column layers (23) in the one direction, and a body region width (W2), which is a length of the body region (24) in the one direction, are different from each other.

### [Supplementary Note 1-6]

The semiconductor device of Supplementary Note 1-5, wherein the column layer width (W1) is smaller than the body region width (W2).

### [Supplementary Note 1-7]

The semiconductor device of Supplementary Note 1-5, wherein the column layer width (W1) is larger than the body region width (W2).

### [Supplementary Note 1-8]

The semiconductor device of any one of Supplementary Note 1-1 to Supplementary Note 1-7, further comprising: a first electrode (2) disposed on the first surface (33) of the semiconductor layer (22) and electrically connected to the first region (25) and the body region (24).

### [Supplementary Note 1-9]

The semiconductor device of any one of Supplementary Note 1-1 to Supplementary Note 1-8, further comprising: a gate insulating film (27) formed in the first surface (33) of the semiconductor layer (22) and arranged to straddle two body regions (24) of the body regions (24) adjacent to each other in the one direction and a gate electrode (28) formed on the gate insulating film.

### [Supplementary Note 1-10]

The semiconductor device of Supplementary Note 1-9, wherein the gate electrode (28) includes: a first portion (51) extending in the one direction in a plan view, a second portion (52) extending in a direction perpendicular to the one direction, and an intersection portion (53) where the first portion and the second portion intersect.

### [Supplementary Note 1-11]

The semiconductor device of any one of Supplementary Note 1-1 to Supplementary Note 1-8, further comprising: at least one insulating film (27 and 72) formed in the first surface (33) of the semiconductor layer (22) and arranged to straddle two body regions (24) of the body regions (24) adjacent to each other in the one direction, wherein the at least one insulating film (27 and 72) includes a first insulating film (27) and a second insulating film (72) which are alternately formed in the one direction with the body region (24) interposed between the first insulating film (27) and the second insulating film (72), wherein a gate electrode (28) is formed on the first insulating film (27), and wherein a dummy gate electrode (71) electrically connected to a first electrode (2) is formed on the second insulating film (72).

### [Supplementary Note 1-12]

The semiconductor device of Supplementary Note 1-11, wherein the gate electrode (28) has a band shape extending in a direction perpendicular to the one direction in a plan view, and wherein the dummy gate electrode (71) has a band shape extending in a direction perpendicular to the one direction in a plan view.

### [Supplementary Note 1-13]

The semiconductor device of any one of Supplementary Note 1-1 to Supplementary Note 1-12, wherein each of the plurality of column layers (23) includes a concave and convex side surface (35) formed by repeatedly arranging a convex portion (36) and a concave portion (37) in the thickness direction of the semiconductor layer (22).

### [Supplementary Note 1-14]

The semiconductor device of any one of Supplementary Note 1-1 to Supplementary Note 1-13, wherein each of the plurality of element structures (41) includes a planar gate structure.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor layer having a first conductivity type and including a first surface and a second surface on an opposite side of the first surface;
a plurality of element structures formed in the first surface of the semiconductor layer at equal intervals in one direction; and
a super junction structure formed in the semiconductor layer,
wherein each of the plurality of element structures includes:
a body region having a second conductivity type and formed in the first surface of the semiconductor layer; and
a first region having the first conductivity type and formed in a surface of the body region,
wherein the super junction structure includes a plurality of column layers having the second conductivity type formed in the semiconductor layer at equal intervals in the one direction and extending in a thickness direction of the semiconductor layer, and
wherein an inter-body region pitch, which is an arrangement interval of the body regions of the plurality of element structures in the one direction, is different from an inter-column layer pitch, which is an arrangement interval of the plurality of column layers in the one direction.

2. The semiconductor device of claim 1, wherein the inter-body region pitch is shorter than the inter-column layer pitch.

3. The semiconductor device of claim 1, wherein the inter-body region pitch is longer than the inter-column layer pitch.

4. The semiconductor device of claim 1, wherein the plurality of column layers include a column layer disposed below the body region to be in contact with the body region.

5. The semiconductor device of claim 1, wherein a column layer width, which is a length of a column layer of the plurality of column layers in the one direction, and a body region width, which is a length of the body region in the one direction, are different from each other.

6. The semiconductor device of claim 5, wherein the column layer width is smaller than the body region width.

7. The semiconductor device of claim 5, wherein the column layer width is larger than the body region width.

8. The semiconductor device of claim 1, further comprising:
a first electrode disposed on the first surface of the semiconductor layer and electrically connected to the first region and the body region.

9. The semiconductor device of claim 1, further comprising:
a gate insulating film formed in the first surface of the semiconductor layer and arranged to straddle two body regions of the body regions adjacent to each other in the one direction; and
a gate electrode formed on the gate insulating film.

10. The semiconductor device of claim 9, wherein the gate electrode includes:
a first portion extending in the one direction in a plan view;
a second portion extending in a direction perpendicular to the one direction; and
an intersection portion where the first portion and the second portion intersect.

11. The semiconductor device of claim 1, further comprising:
at least one insulating film formed in the first surface of the semiconductor layer and arranged to straddle two body regions of the body regions adjacent to each other in the one direction,
wherein the at least one insulating film includes a first insulating film and a second insulating film which are alternately formed in the one direction with the body region interposed between the first insulating film and the second insulating film,
wherein a gate electrode is formed on the first insulating film, and
wherein a dummy gate electrode electrically connected to a first electrode is formed on the second insulating film.

12. The semiconductor device of claim 11, wherein the gate electrode has a band shape extending in a direction perpendicular to the one direction in a plan view, and
wherein the dummy gate electrode has a band shape extending in a direction perpendicular to the one direction in a plan view.

13. The semiconductor device of claim 1, wherein each of the plurality of column layers includes a concave and convex side surface formed by repeatedly arranging a convex portion and a concave portion in the thickness direction of the semiconductor layer.

14. The semiconductor device of claim 1, wherein each of the plurality of element structures includes a planar gate structure.
